(19) United States
(12) Patent Application Publication
(10) Pub. No.: US 2022/0263425 A1
(43) Pub. Date: Aug. 18, 2022

(54) ELECTRIC CIRCUIT DEVICE

(71) Applicant: HITACHI ASTEMO, LTD., Hitachinaka-shi, Ibaraki (JP)

(72) Inventors: Takuma HAKUTO, Hitachinaka-shi (JP); Takayuki OSHIMA, Hitachinaka-shi (JP); Akira MATSUSHITA, Hitachinaka-shi (JP)

(73) Assignee: HITACHI ASTEMO, LTD., Hitachinaka-shi, Ibaraki (JP)

(21) Appl. No.: 17/628,997

(22) PCT Filed: Jul. 14, 2020
(86) PCT No.: PCT/JP2020/027320

§ 371 Date: Jan. 21, 2022

(30) Foreign Application Priority Data
Jul. 24, 2019 (JP) 2019-136461

(51) Int. Cl. H02M 7/00; H02M 1/34; H01L 23/367

(52) U.S. Cl. CPC H02M 7/003; H01L 23/367; H02M 1/34

(57) ABSTRACT

An inductance reduction effect is improved by reducing the distortion of an inductance loop generated when a switching element is turned on and off. An upper arm circuit portion (201U) and a lower arm circuit portion (201L) are provided so as to be shifted in the second direction orthogonal to the first direction in which the upper arm circuit portion (201U) and the lower arm circuit portion (201L) are separated from each other, and at least a part of a snubber circuit connection portion region (202) constituted by a positive electrode terminal portion (181), a negative electrode terminal portion (155), and a snubber element (30) is provided in the first region generated by shifting the upper arm circuit portion (201U) from the lower arm circuit portion (201L) in the second direction.

### TECHNICAL FIELD

The present invention relates to an electric circuit device.

### BACKGROUND ART

Since an electric circuit device such as a power semiconductor module having a power switching element and performing power conversion has high conversion efficiency, the electric circuit device is widely used for consumer use, in-vehicle use, railway use, electric substation equipment, and the like. In such an electric circuit device having a switching element, there is a possibility that the voltage increases due to self-inductance when the switching element is turned on or off, and a surge-like high voltage is generated.

As a structure for suppressing an increase in voltage due to inductance, there is known a power semiconductor module in which a snubber element including a snubber capacitor is disposed between a power switching element and a smoothing capacitor to reduce wiring inductance. As an example of such a power semiconductor module, there is a structure in which an upper arm circuit portion and a lower arm circuit portion are juxtaposed, a positive electrode side lead connected to the upper arm circuit portion and a negative electrode side lead connected to the lower arm circuit portion extend above the upper arm circuit portion and the lower arm circuit portion, respectively, and a snubber element is disposed between the positive electrode side lead and the negative electrode side lead (see, for example, PTL 1).

### CITATION LIST

### Patent Literature

PTL 1: JP 2014-53516 A

### SUMMARY OF INVENTION

### Technical Problem

In the power semiconductor module disclosed in PTL 1, the snubber element is disposed above the upper arm circuit portion and the lower arm circuit portion. The length of the circuit in the snubber element connection portion region is shorter than the length of the circuit in the arrangement direction of the upper and lower arm series circuit portions configured by juxtaposing the upper arm circuit portion and the lower arm circuit portion. Therefore, in the inductance loop generated by turning on and off the switching element, the snubber element connection portion region has a convex shape narrower than the upper and lower arm series circuit portions. That is, the inductance loop is a protruding loop in which a recess is formed in a region flowing from the upper and lower arm series circuit portions to the snubber element connection portion region and in a region flowing from the snubber element connection portion region to between the upper and lower arm series circuit portions. As described above, since distortion is formed in the inductance loop and a useless region is generated, a sufficient inductance reduction effect cannot be obtained.

### Solution to Problem

An electric circuit device according to one aspect of the present invention includes an upper arm circuit portion including a first switching element, a lower arm circuit portion provided to be separated from the upper arm circuit portion in a first direction and having a second switching element, a positive electrode terminal portion electrically connected to the upper arm circuit portion, a negative electrode terminal portion provided with a gap from the upper arm circuit portion in the first direction and electrically connected to the lower arm circuit portion, a snubber element provided on a region including the gap between the positive electrode terminal portion and the negative electrode terminal portion and connecting the positive electrode terminal portion and the negative electrode terminal portion, and a heat dissipation member stacked on the upper arm circuit portion and the lower arm circuit portion through an insulating layer, wherein the upper arm circuit portion and the lower arm circuit portion are provided to be shifted from each other in a second direction orthogonal to the first direction, and at least a part of a snubber circuit connection portion region constituted by the positive electrode terminal portion, the negative electrode terminal portion, and the snubber element is provided in a first region generated when the upper arm circuit portion and the lower arm circuit portion are shifted in the second direction.

### Advantageous Effects of Invention

According to the present invention, the distortion of the inductance loop is reduced, and the inductance reduction effect can be improved.

### BRIEF DESCRIPTION OF DRAWINGS

FIG. 1 is an external perspective view of an embodiment of an electric circuit device according to the present invention.

FIG. 2 is a perspective view of the electric circuit device illustrated in FIG. 1 in a state in which a sealing resin is removed.

FIG. 3 is a perspective view of the electric circuit device illustrated in FIG. 2 from which a heat dissipation member in the intermediate body is removed.

FIG. 4 is a circuit diagram illustrating an example of a circuit of the electric circuit device illustrated in FIG. 1.

FIG. 5 illustrates a conductor pattern provided on an insulating member in the intermediate body of the electric circuit device illustrated in FIG. 3, FIG. 5(A) is a perspective view of a source side insulating member as viewed from above, and FIG. 5(B) is a perspective view of a drain side insulating member as viewed from above.

FIG. 6 illustrates a mounting structure of the intermediate body of the electric circuit device illustrated in FIG. 3, FIG. 6(A) is a plan view illustrating a mounting state on the drain side insulating substrate side as seen through the source side insulating substrate from above, and FIG. 6(B) is a plan view illustrating a mounting state on the source side insulating substrate side as seen from above.

FIG. 7 is a cross-sectional view taken along line VII-VII of the electric circuit device illustrated in FIG. 1. Line VII-VII of the electric circuit device illustrated in FIG. 1 passes through line VII-VII in the mounted state on the drain side insulating substrate side in FIG. 6(B).

FIG. 8 is a cross-sectional view taken along line VIII-VIII of the electric circuit device illustrated in FIG. 1. Line VIII-VIII of the electric circuit device illustrated in FIG. 1 passes through line VIII-VIII in the mounted state on the drain side insulating substrate side in FIG. 6(B).

FIG. 9 is a layout diagram of a mounting state on the drain side insulating substrate side illustrated in FIG. 6(A).

FIG. 10(A) is a plan view illustrating an eddy current loop generated in a plane in a mounted state on the drain side insulating substrate side illustrated in FIG. 6(A), and FIG. 10(B) is a perspective view illustrating an eddy current loop generated in a heat dissipation member of the electric circuit device.

FIG. 11 illustrates a modification of the electric circuit device according to the present invention,

FIG. 11(A) is a layout diagram of a mounted state on the drain side insulating substrate side corresponding to FIG. 9, and FIG. 11(B) is a plan view illustrating a conductor pattern of a source side insulating member.

### DESCRIPTION OF EMBODIMENTS

Embodiments of the present invention will be described below with reference to the accompanying drawings. The following description and drawings are examples for describing the present invention, and are omitted and simplified as appropriate for the sake of clarity of description. The present invention can be carried out in various other forms. Unless otherwise specified, each component may be singular or plural.

Positions, sizes, shapes, ranges, and the like of the respective components illustrated in the drawings may not represent actual positions, sizes, shapes, ranges, and the like in order to facilitate understanding of the invention. Therefore, the present invention is not necessarily limited to the positions, sizes, shapes, ranges, and the like disclosed in the drawings.

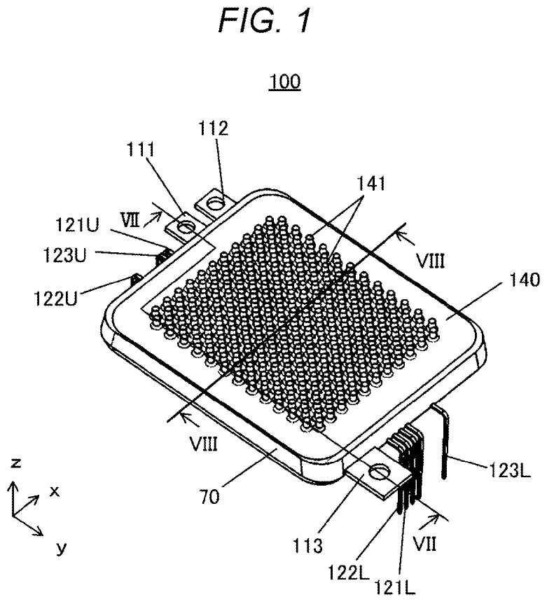

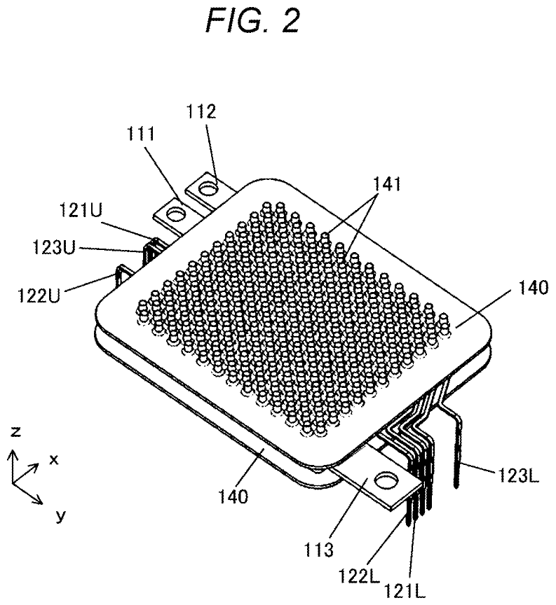

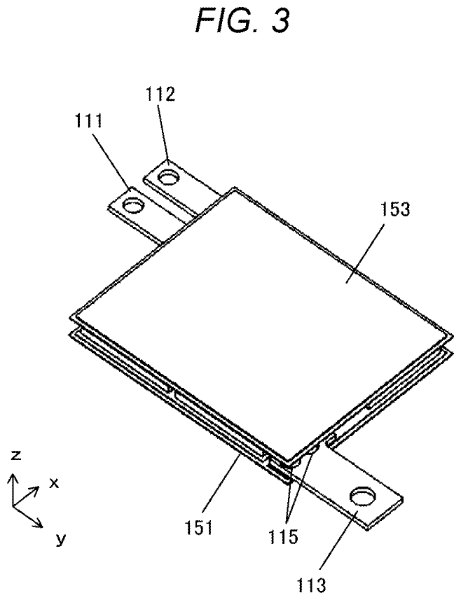

FIG. 1 is an external perspective view of an embodiment of an electric circuit device according to the present invention. FIG. 2 is a perspective view of the electric circuit device illustrated in FIG. 1 in a state in which a sealing resin is removed, and FIG. 3 is a perspective view of the electric circuit device illustrated in FIG. 2 in a state in which a heat dissipation member in an intermediate body is removed.

In the following description, the x direction, the y direction, and the z direction are as illustrated in the drawings.

As illustrated in FIG. 1, an electric circuit device 100 has a substantially flat rectangular parallelepiped shape.

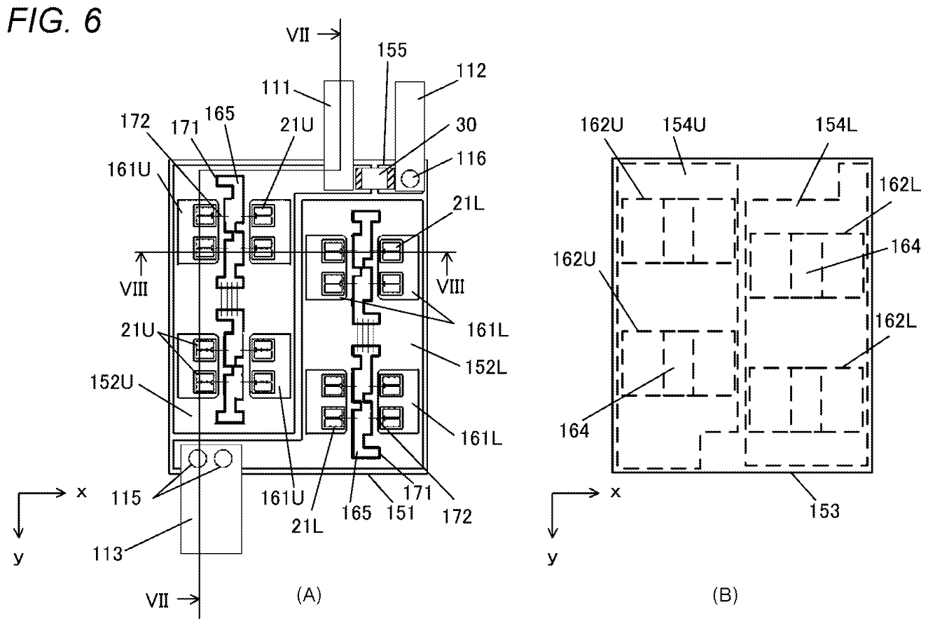

The electric circuit device 100 includes a pair of upper and lower heat dissipation members 140 (see FIG. 2) and a sealing resin 70 that seals the periphery between the pair of heat dissipation members 140. As will be described later, a plurality of semiconductor elements 21U and 21L (see FIG. 6 and the like) are sealed inside the pair of heat dissipation members 140 and the sealing resin 70. The semiconductor elements 21U and 21L are power semiconductor elements. The electric circuit device 100 will be exemplified as a power semiconductor module hereinafter.

As illustrated in FIGS. 1 and 2, a positive electrode lead terminal 111 and a negative electrode lead terminal 112 of a strong electric circuit system protrude from one side of the electric circuit device 100 in the −y direction. A drain lead terminal 121U, a source lead terminal 122U, and a gate lead terminal 123U of a control circuit system protrude from one side of the electric circuit device 100 in the −y direction.

An AC lead terminal 113 of a strong electric circuit system protrudes from one side of the electric circuit device 100 in the y direction. A drain lead terminal 121L, a source lead terminal 122L, and a gate lead terminal 123L of the control circuit system protrude from one side of the electric circuit device 100 in the −y direction. A sense lead terminal (no reference sign) or the like also protrudes from one side of the electric circuit device 100 in the y direction.

The heat dissipation member 140 includes a plurality of heat dissipation pins 141 protruding outward. The heat dissipation pins 141 are integrally molded with the heat dissipation member 140 by, for example, aluminum die casting or the like. The heat dissipation pins 141 may be separately formed and fixed to the base member. The heat dissipation member 140 may be formed of another metal material having good heat dissipation other than aluminum.

As illustrated in FIG. 3, the electric circuit device 100 includes a pair of upper and lower insulating members 151 and 153 thermally coupled to the heat dissipation member 140. The plurality of semiconductor elements 21U and 21L (see FIG. 6 and the like) and a member on which the semiconductor elements 21U and 21L are mounted (to be described below) are provided between the pair of upper and lower insulating members 151 and 153.

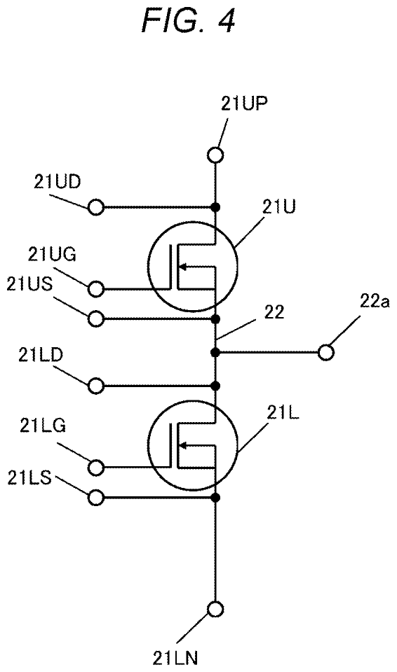

FIG. 4 is a circuit diagram illustrating an example of a circuit of the electric circuit device illustrated in FIG. 1.

The electric circuit device 100 includes an upper and lower arm series circuit in which the semiconductor element 21U operating as an upper arm circuit portion and the semiconductor element 21L operating as a lower arm circuit portion are connected in series.

Note that the semiconductor elements 21U and 21L of the upper and lower arm circuit portions are each usually configured by a plurality of semiconductor elements.

In the present embodiment, the electric circuit device 100 is illustrated as a 2 in 1 package in which the upper arm circuit portion and the lower arm circuit portion are integrated. The semiconductor elements 21U and 21L are formed of, for example, metal oxide semiconductor field effect transistors (MOSFETs). For the electric circuit device 100 according to the present embodiment, particularly, a silicon carbide (SiC)-MOSFET that operates at a high speed can be used. The semiconductor elements 21U and 21L will be described below as MOSFETs.

A description will be given with reference to FIGS. 1 and 2. The drain lead terminal 121U is connected to a drain terminal 21UD of the semiconductor element 21U, the source lead terminal 122U is connected to a source terminal 21US, and a gate lead terminal 123U is connected to the gate terminal 21UG. A positive electrode lead terminal 111 is connected to a positive electrode terminal portion 21UP of the semiconductor element 21U.

The drain lead terminal 121L is connected to a drain terminal 21LD of the semiconductor element 21L, the source lead terminal 122L is connected to the source terminal 21LS, and a gate lead terminal 123L is connected to the gate terminal 21LG. A negative electrode lead terminal 112 is connected to a negative electrode terminal portion 21LN of the semiconductor element 21L.

The source terminal 21US of the semiconductor element 21U and the drain terminal 21LD of the semiconductor element 21L are connected by a conductor 22. The gate terminal 21UG of the semiconductor element 21U and the gate terminal 21LG of the semiconductor element 21L are connected to a driver circuit (not illustrated). The upper and lower arm series circuit outputs AC power of one of three phases of a U phase, a V phase, and a W phase from an AC terminal portion 22a of the conductor 22 corresponding to each phase winding of an armature winding such as a motor generator (not illustrated). An AC lead terminal 123 is connected to the AC terminal portion 22a.

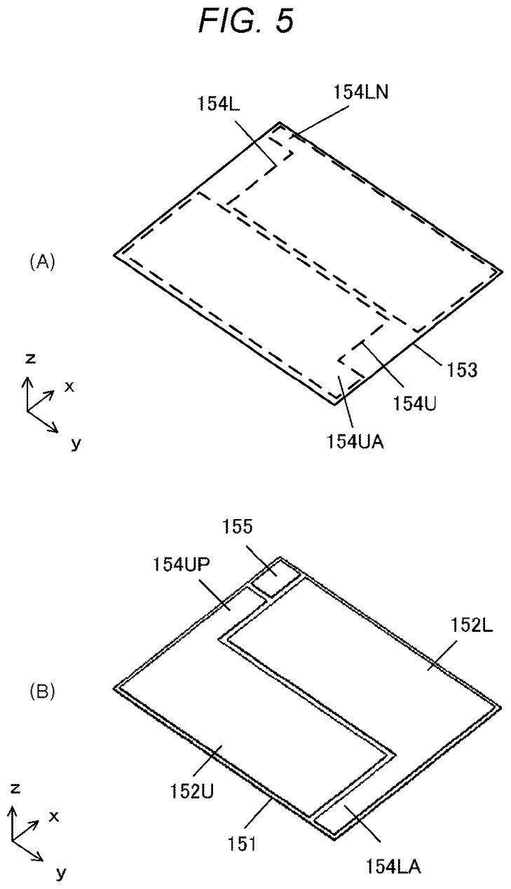

FIG. 5 illustrates a conductor pattern provided on an insulating member in the intermediate body of the electric circuit device illustrated in FIG. 3. FIG. 5(A) is a perspective view of a source side insulating member as viewed from above. FIG. 5(B) is a perspective view of a drain side insulating member as viewed from above.

As illustrated in FIG. 5(A), the source side conductor patterns 154U and 154L are integrally formed on one surface of the source side insulating member 153 on the semiconductor elements 21U and 21L side (−z direction side). As illustrated in FIG. 5(B), drain side conductor patterns 152U and 152L and a negative electrode connection pattern 155 are integrally formed on one surface of the drain side insulating member 151 on the semiconductor elements 21U and 21L side (+z direction side).

The source side conductor patterns 154U and 154L, the drain side conductor patterns 152U and 152L, and the negative electrode connection pattern 155 are formed of, for example, a copper-based metal. A metal material having good conductivity and heat conductivity other than the copper-based metal may be used.

The following is a detailed description of the junction structure between the positive electrode lead terminal 111, the negative electrode lead terminal 112, and the AC lead terminal 113, which are also illustrated in FIG. 3, and the conductor patterns 152U and 152L on the drain side and the conductor patterns 154U and 154L on the source side illustrated in FIGS. 5(A) and 5(B).

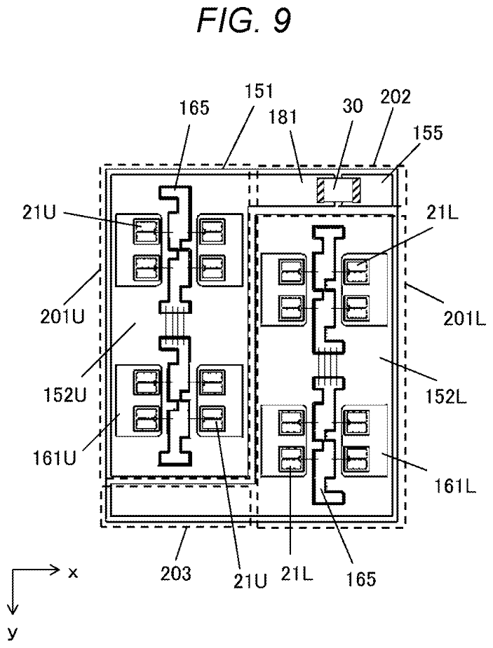

The positive electrode lead terminal 111 is joined to the partial region pattern 152UP (corresponding to the positive electrode terminal portion 21UP in FIG. 4 and the positive electrode connection terminal 181 in FIG. 9) of the conductor pattern 152U provided on the drain side insulating member 151. The conductor pattern 152U on the drain side is a pattern electrically connected to the drain terminal 21UD of the semiconductor element 21U constituting the upper arm circuit in FIG. 4.

The AC lead terminal 113 is joined to a partial region pattern 152LA (corresponding to the conductor patterns of the AC terminal portion 22a in FIG. 4 and the AC terminal connection portion 203 in FIG. 9) of the conductor pattern 152L provided on the drain side insulating member 151. The conductor pattern 152L on the drain side is a pattern electrically connected to the source terminal 21US of the semiconductor element 21U constituting the upper arm circuit in FIG. 4.

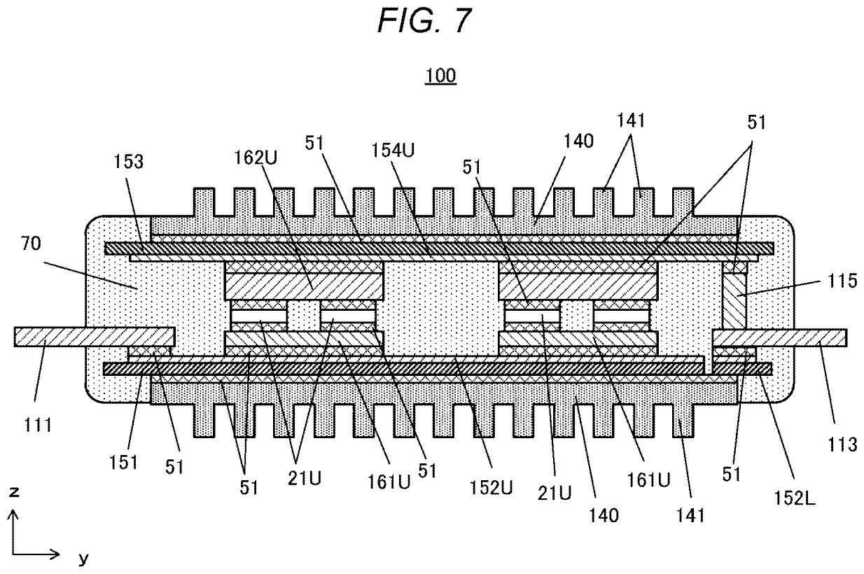

A partial region 154UA of the conductor pattern 154U provided in the source side insulating member 153 and the partial region 152LA of the conductor pattern 152L provided in the drain side insulating member 151 are electrically connected by an upper/lower conducting conductor 115 illustrated in FIG. 7 to be described later. That is, the source terminal 21US of the semiconductor element 21U of the upper arm circuit and the drain terminal 21LD of the semiconductor element 21L of the lower arm circuit are electrically connected.

The partial region 154LN of the conductor pattern 154L provided in the source side insulating member 153 and the negative electrode connection pattern 155 which is formed as an isolated pattern in the drain side insulating member 151 and to which the negative electrode lead terminal 112 is joined are electrically connected by an upper/lower conducting conductor 116 illustrated in FIG. 6(A) as described later. As a result, the conductor pattern 154L is electrically connected to the negative electrode lead terminal 112.

A snubber element 30 described later with reference to FIG. 6 is interposed between the isolated source side conductor pattern 155 in FIG. 5(B) and the partial region pattern 152UP of the drain side conductor pattern 152U. That is, the snubber element 30 is provided between the partial region pattern 152UP on the drain side to which the positive electrode lead terminal 111 is connected and the isolated negative electrode connection pattern 155 to which the negative electrode lead terminal 112 is connected. In other words, the snubber element 30 is interposed between the drain terminal 21UD of the semiconductor element 21U of the upper arm circuit and the source terminal 21LS of the semiconductor element 21L of the lower arm circuit.

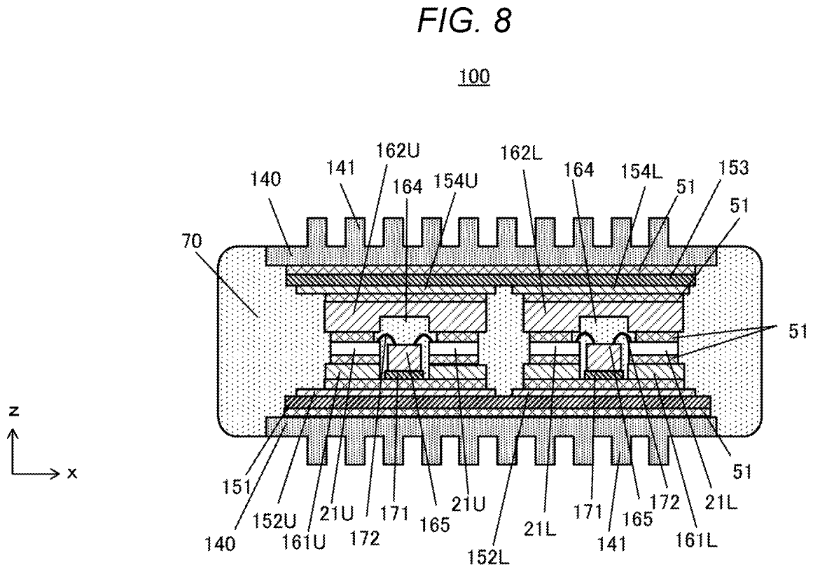

FIG. 6 illustrates a mounting structure of the intermediate body of the electric circuit device illustrated in FIG. 3. FIG. 6(A) is a plan view illustrating a mounting state on the drain side insulating substrate side as seen through the source side insulating substrate from above. FIG. 6(B) is a plan view illustrating a mounting state on the source side insulating substrate side as seen from above. FIG. 7 is a cross-sectional view taken along line VII-VII of the electric circuit device illustrated in FIG. 1. Line VII-VII of the electric circuit device illustrated in FIG. 1 passes through line VII-VII in the mounted state on the drain side insulating substrate side in FIG. 6(A). FIG. 8 is a cross-sectional view taken along line VIII-VIII of the electric circuit device illustrated in FIG. 1. Line VIII-VIII of the electric circuit device illustrated in FIG. 1 passes through line VIII-VIII in the mounted state on the drain side insulating substrate side in FIG. 6(A).

Heat spreaders 161U and 161L are joined onto the drain side conductor patterns 152U and 152L of the drain side insulating member 151. The drain side conductor patterns 152U and 152L and the heat spreaders 161U and 161L are joined to each other by a conductive joining material 51 (FIGS. 7 and 8) such as solder or a joining paste for forming a sintered metal.

As illustrated in FIG. 6(A), eight semiconductor elements 21U and eight semiconductor elements 21L are mounted on the drain side conductor pattern 152U and the drain side conductor pattern 152L, respectively. The eight semiconductor elements 21U are arranged in two rows in the x direction, four in each row, and the eight semiconductor elements 21L are also arranged in two rows in the x direction, four in each row (y direction).

The two semiconductor elements 21U in each row are joined to one heat spreader 161U as a pair. The heat spreaders 161U are arranged in two rows spaced apart in the x direction. A gate conductor 165 is disposed between heat spreaders 161U arranged in two rows.

Similarly, two semiconductor elements 21L in each row are joined to one heat spreader 161L as a pair. The heat spreaders 161L are arranged in two rows spaced apart in the x direction. A gate conductor 165 is disposed between heat spreaders 161U arranged in two rows.

Each gate conductor 165 is fixed to the drain side conductor patterns 152U and 152L via an insulating layer 171 (see FIGS. 6(A) and 8).

As illustrated in FIGS. 7 and 8, the drain terminals 21UD and 21LD (see FIG. 4) of semiconductor elements 21U and 21L are joined to the heat spreaders 161U and 161L by the conductive joining material 51. The gate terminals 21UG and 21LG of the semiconductor elements 21U and 21L are joined to the gate conductors 165 by wires 172 (see FIGS. 6 (A) and 8).

As illustrated in FIG. 7, the positive electrode lead terminal 111 is joined to the drain side conductor pattern 152U by the conductive joining material 51. Although not illustrated, similarly, the negative electrode lead terminal 112 (see FIG. 1) is joined to the drain side conductor pattern 152L by the conductive joining material 51.

Although not illustrated, the drain lead terminal 121U (see FIG. 1) is connected to the drain side conductor pattern 152U, and the gate lead terminal 123U (see FIG. 1) is connected to the gate conductor 165. Likewise, although not illustrated, the drain lead terminal 121L (see FIG. 1) is connected to the drain side conductor pattern 152L, and the gate lead terminal 123L (see FIG. 1) is connected to the gate conductor 165.

In addition, as illustrated in FIG. 7, the AC lead terminal 113 is joined to the drain side conductor pattern 152L by the conductive joining material 51.

The upper/lower conducting conductor 115 is integrally formed with the AC lead terminal 113 by, for example, caulking or the like. The upper/lower conducting conductor 115 may be joined to the AC lead terminal 113 with a conductive joining material. Although described with reference to FIG. 7, the upper/lower conducting conductor 115 correspond to the conductor 22 of FIG. 4.

As illustrated in FIG. 6, the drain side conductor pattern 152U to which the positive electrode lead terminal 111 is joined and the negative electrode connection pattern 155 to which the negative electrode lead terminal 112 is joined are separated between the positive electrode lead terminal 111 and the negative electrode lead terminal 112. In a region where the positive electrode lead terminal 111 and the negative electrode lead terminal 112 are separated, the snubber element 30 for connecting the drain side conductor pattern 152U and the negative electrode connection pattern 155 is mounted. Although not illustrated, t snubber element 30 incorporates a resistor and a capacitor connected in series.

As illustrated in FIG. 6(B), the heat spreaders 162U and 162L are joined to the source side conductor patterns 154U and 154L provided on the source side insulating member 153, respectively, by a conductive joining material 51 (see FIGS. 7 and 8).

As illustrated in FIG. 7, the source terminals 21US and 21LS (see FIG. 4) of the semiconductor elements 21U and 21L are joined to the heat spreaders 162U and 162L, respectively, by the conductive joining material 51.

As illustrated in FIGS. 6 and 8, grooves 164 extending in the Y direction are formed in the center portions of the heat spreaders 162U and 162L, respectively, and contact between the gate terminals 21UG and 21LG of the semiconductor elements 21U and 21L and the wires 172 connecting the gate conductors 165 is avoided.

The heat spreaders 161U, 161L, 162U, and 162L are formed to have a larger thickness and a larger heat capacity than the drain side conductor patterns 152U and 152L and the source side conductor patterns 154U and 154L. Therefore, even when the temperature of the semiconductor elements 21U and 21L suddenly rises, heat is accumulated, delayed, and dissipated. As a result, the change in the amount of heat dissipated from the heat spreaders 161U, 161L, 162U, and 162L becomes gentle, and damage to the semiconductor elements 21U and 21L can be suppressed.

As illustrated in FIG. 7, the upper/lower conducting conductor 115 is joined to the source side conductor pattern 154U provided on the source side insulating member 153 by the conductive joining material 51. The upper/lower conducting conductor 115 corresponds to the conductor 22 in FIG. 4, and electrically connects the source terminal 21US (see FIG. 4) of the semiconductor element 21U constituting the upper arm circuit portion to the drain terminal 21LD (see FIG. 4) of the semiconductor element 21L constituting the lower arm circuit portion.

Although not illustrated as a cross-sectional view, the upper/lower conducting conductor 116 illustrated in FIG. 6(A) also electrically connects the negative electrode connection pattern 155 to the source side conductor pattern 154L formed in the source side insulating member 153 with the same structure as the upper/lower conducting conductor 115.

The surfaces of the drain side and source side insulating members 151 and 153 which are located on the opposite side to the semiconductor elements 21U and 21L are joined to the heat dissipation member 140 by the conductive joining material 51. The semiconductor elements 21U and 21L, the heat spreaders 161U, 161L, 162U, and 162L, and the drain side and source side insulating members 151 and 153 are sandwiched and mounted between the pair of upper and lower heat dissipation members 140, and in this state, are sealed by the sealing resin 70 filled between the pair of upper and lower heat dissipation members 140. The sealing resin 70 is provided to cover the outer peripheral edges of the pair of upper and lower heat dissipation members 140.

FIG. 9 is a layout diagram of a mounting state on the drain side insulating substrate side illustrated in FIG. 6(A).

The electric circuit device 100 includes four regions of an upper arm circuit portion 201U, a lower arm circuit portion 201L, a snubber circuit connection portion region 202, and an AC terminal connection portion 203.

The four regions form a rectangular planar region. This will be described below.

The upper arm circuit portion 201U is a region which is disposed between the drain side conductor pattern 152U and the source side conductor pattern 154U and in which the eight semiconductor elements 21U are mounted.

The lower arm circuit portion 201L is a region which is disposed between the drain side conductor pattern 152L and the source side conductor pattern 154L and in which the eight semiconductor elements 21L are mounted.

The snubber circuit connection portion region 202 is a region in which the positive electrode terminal portion 181 (corresponding to the positive electrode terminal portion 21UP in FIG. 4) to which the positive electrode lead terminal 111 (see FIG. 6 (A)) of the drain side conductor pattern 152U which extends to the lower arm circuit portion side (±x direction) is joined, the negative electrode connection pattern 155, and the snubber element 30 that connects the drain side conductor pattern 152U to the negative electrode connection pattern 155 are mounted.

The AC terminal connection portion 203 is a region where the drain side conductor pattern 152L extends toward the lower arm circuit portion (−x direction) and is connected to the AC terminal portion 22a (see FIG. 4).

The upper arm circuit portion 201U and the lower arm circuit portion 201L are arranged to be separated from each other in the x direction. The upper arm circuit portion 201U and the lower arm circuit portion 201L have rectangular shapes having substantially the same lengths in the separating direction (x direction) and the direction orthogonal to the separating direction (y direction).

The upper arm circuit portion 2010 and the lower arm circuit portion 201L are shifted in the direction (y direction) orthogonal to the separating direction. Referring to FIG. 9, the upper arm circuit portion 201U is shifted to a position protruding in the −y direction with respect to the lower arm circuit portion 201L. In other words, one side of the lower arm circuit portion 201L which extends in the x direction on the −y direction end portion side is shifted in the +y direction by a predetermined length from one side of the upper arm circuit portion 201U which extends in the x direction on the −y direction end portion side.

The snubber circuit connection portion region 202 is provided in a rectangular region formed by shifting the lower arm circuit portion 201L in the +y direction with respect to the upper arm circuit portion 201U.

One side of the upper arm circuit portion 201U which extends in the x direction on the +y direction end portion side is shifted in the −y direction by a predetermined length from one side of the lower arm circuit portion 201L which extends in the x direction on the +y direction end portion side. The AC terminal connection portion 203 is provided in a rectangular region where the upper arm circuit portion 201U is shifted in the −y direction from the lower arm circuit portion 201L.

As described above, the upper arm circuit portion 201U and the lower arm circuit portion 201L are formed in rectangular shapes having substantially the same lengths in the x direction and the y direction. Therefore, the snubber circuit connection portion region 202 and the AC terminal connection portion 203 have rectangular shapes having substantially the same lengths in the x direction and the y direction. That is, each of the four regions of the upper arm circuit portion 201U, the lower arm circuit portion 201L, the snubber circuit connection portion region 202, and the AC terminal connection portion 203 forms a rectangular planar region.

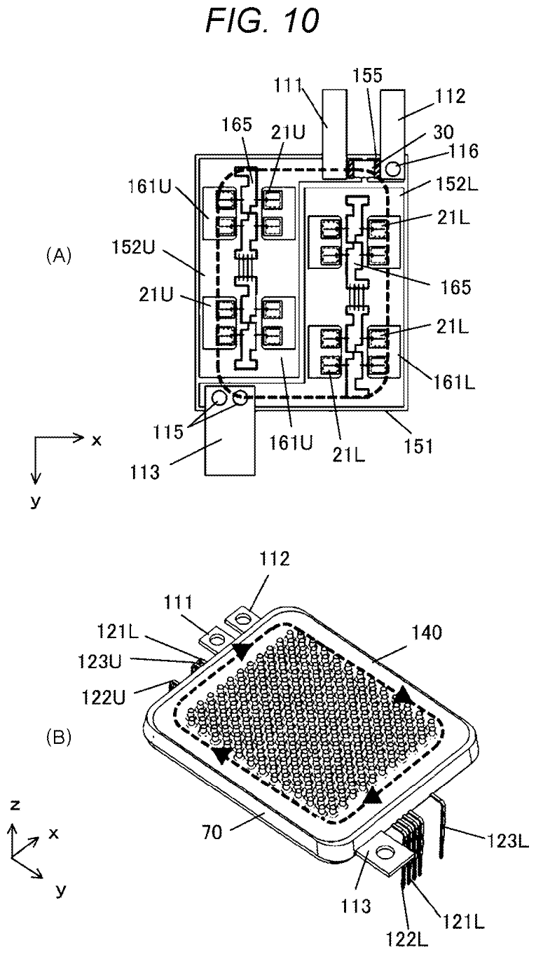

FIG. 10(A) is a plan view illustrating an eddy current loop generated in the plane in the mounted state on the drain side insulating substrate side illustrated in FIG. 6(A).

When the semiconductor elements 21U and 21L are turned on and off, self-inductance occurs, and an eddy current loop in a direction that prevents a steady current occurs. In this embodiment, as described above, the four regions of the upper arm circuit portion 201U, the lower arm circuit portion 201L, the snubber circuit connection portion region 202, and the AC terminal connection portion 203 form a rectangular planar region.

Therefore, the eddy currents generated in the electric circuit according to the present embodiment form a substantially rectangular loop without distortion as illustrated in FIG. 10(A). As described above, the distortion of the inductance loop is reduced, and hence the inductance reduction effect can be improved.

FIG. 10(B) is a perspective view illustrating an eddy current loop generated in the heat dissipation member of the electric circuit device.

As illustrated in FIG. 10(B), an eddy current loop in a direction opposite to the electric circuit is generated in the heat dissipation member 140 provided via the insulating layer in the electric circuit in which the eddy current is generated.

—Modification—

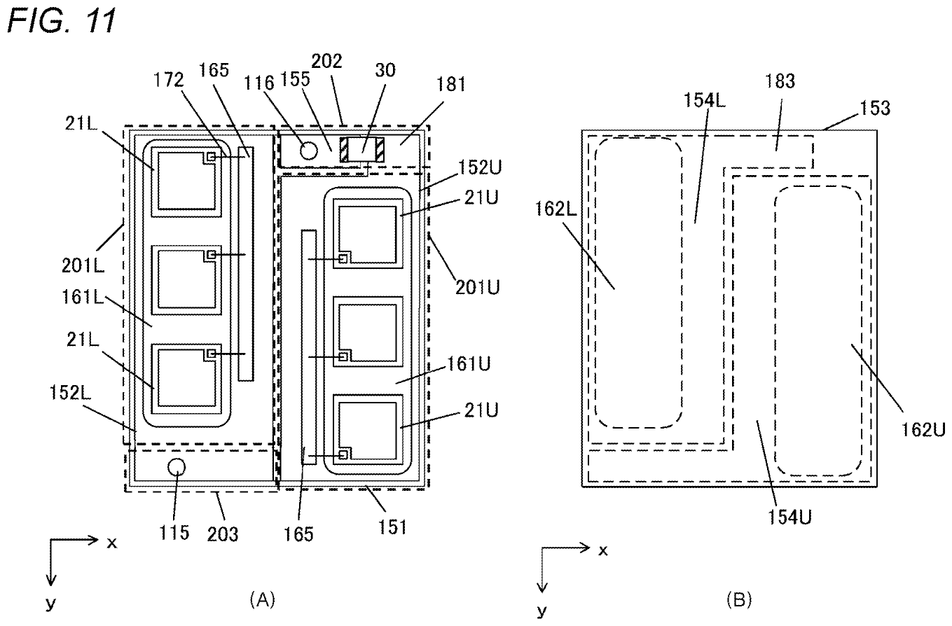

FIG. 11 illustrates a modification of the electric circuit device according to the present invention, FIG. 11(A) is a layout diagram of a mounted state on the drain side insulating substrate side corresponding to FIG. 9, and FIG. 11(B) is a plan view illustrating a conductor pattern of a source side insulating member.

In the layout on the drain side insulating substrate side illustrated in FIG. 9, the upper arm circuit portion 201U protrudes in the −y direction with respect to the lower arm circuit portion 201L. On the other hand, in the modified example illustrated in FIG. 11, the lower arm circuit portion 201L protrudes in the −y direction with respect to the upper arm circuit portion 201U.

As illustrated in FIG. 11(A), the heat spreaders 161U and 161L are joined onto the drain side conductor patterns 152U and 152L of the drain side insulating member 151, respectively. The three semiconductor elements 210 are provided on the heat spreader 161U, and the three semiconductor elements 21L are provided on the heat spreader 161L. The drain terminals 21UD and 21LD of the semiconductor elements 210 and 21L are electrically connected to the door heat spreaders 161U and 161L, respectively.

On the drain side conductor patterns 152U and 152L, the gate conductors 165 are provided through an insulating layer (not illustrated). The gate terminals 21UG and 21LG of the semiconductor elements 210 and 21L are electrically connected to the gate conductors 165 by the wires 172, respectively.

The positive electrode terminal portion 181 is provided on the −y direction end portion side of the drain side conductor pattern 152U. The negative electrode connection pattern 155 is provided on the −y direction end portion side of the drain side insulating member 151. The negative electrode connection pattern 155 is provided separately from the drain side conductor pattern 152L and the positive electrode terminal portion 181. The snubber element 30 is mounted on a separation portion between the negative electrode connection pattern 155 and the positive electrode terminal portion 181. The snubber element 30 electrically connects the negative electrode connection pattern 155 and the positive electrode terminal portion 181. The positive electrode lead terminal 111 is connected to the positive electrode terminal portion 181. The negative electrode lead terminal 112 is connected to the negative electrode connection pattern 155.

In the source side insulating member 153, the source side conductor patterns 154U and 154L having shapes illustrated in FIG. 11(B) are formed. The heat spreaders 162U and 162L are joined onto the source side conductor patterns 154U and 154L, respectively. The heat spreaders 162U and 162L are joined to the drain terminals 21UD and 21LD of the semiconductor elements 21U and 21L, respectively.

The source side conductor pattern 154U has an extending portion 182 extending to the drain side conductor pattern 152L side (−x direction) on the +y direction end portion side. The extending portion 182 of the source side conductor pattern 154U is electrically connected to the drain side conductor pattern 152L by the upper/lower conducting conductor 115. The AC lead terminal 113 is connected to near the connection portion with the upper/lower conducting conductor 115 of the drain side conductor pattern 152L.

The source side conductor pattern 154L has an extending portion 183 extending toward the negative electrode connection pattern 155 side (÷x direction) on the direction end portion side. The extending portion 183 of the source side conductor pattern 154L is electrically connected to the negative electrode connection pattern 155 by the upper/lower conducting conductor 116.

The upper arm circuit portion 201U is a rectangular region having a drain side conductor pattern 152U, a source side conductor pattern 154U, and the three semiconductor elements 21G.

The lower arm circuit portion 201L is a rectangular region including the drain side conductor pattern 152L, the source side conductor pattern 154L, and the three semiconductor elements 21L.

The snubber circuit connection portion region 202 is a region where the negative electrode connection pattern (corresponding to the negative electrode terminal portion 21LN in FIG. 4) 155, the positive electrode terminal portion 181 (corresponding to 21UP in FIG. 4) of the drain side conductor pattern 152U to which the positive electrode lead terminal 111 is connected, and the snubber element 30 that connects the negative electrode connection pattern (negative electrode terminal portion) 155 and the positive electrode terminal portion 181 are mounted.

The AC terminal connection portion 203 is a region where the source side conductor patterns 154U and 154L extend toward the lower arm circuit portion (−x direction) and is connected to the AC terminal portion 22a (see FIG. 4).

The upper arm circuit portion 201U and the lower arm circuit portion 201L are formed in rectangular shapes having substantially the same lengths in the x direction and the y direction.

The upper arm circuit portion 201U has a configuration protruding in the +y direction with respect to the lower arm circuit portion 201L. Accordingly, one side of the upper arm circuit portion 201U which extends in the x direction on the −y direction end portion side is shifted in the +y direction by a predetermined length from one side of the lower arm circuit portion 201L which extends in the x direction on the −y direction end portion side. The snubber circuit connection portion region 202 is provided in a rectangular region where the upper arm circuit portion 201U is shifted in the +y direction from the lower arm circuit portion 201L.

One side of the lower arm circuit portion 201L which extends in the x direction on the +y direction end portion side is shifted in the +y direction by a predetermined length from one side of the upper arm circuit portion 201U which extends in the x direction on the +y direction end portion side (the drain side conductor pattern 152L on which the semiconductor element 21L constituting the lower arm circuit portion 201L is mounted extends to the position of one side of the upper arm circuit portion 201U which extends in the x direction on the +y direction end portion side). The AC terminal connection portion 203 is provided in a rectangular region where the lower arm circuit portion 201L is shifted in the −y direction from the upper arm circuit portion 201U.

As described above, the upper arm circuit portion 201U and the lower arm circuit portion 201L are formed in rectangular shapes having substantially the same lengths in the x direction and the y direction. Therefore, the snubber circuit connection portion region 202 and the AC terminal connection portion 203 have rectangular shapes having substantially the same lengths in the x direction and the y direction. That is, the four regions of the upper arm circuit portion 201U, the lower arm circuit portion 201L, the snubber circuit connection portion region 202, and the AC terminal connection portion 203 form a rectangular planar region.

Therefore, even in the modification, the eddy current generated in the electric circuit forms a substantially rectangular loop without distortion. This can reduce the distortion of the inductance loop and improve the inductance reduction effect.

It is not necessary to provide the entire snubber circuit connection portion region 202 in a rectangular region in which one of the upper arm circuit portion 201U and the lower arm circuit portion 201L is shifted from the other in the x direction or the y direction. At least a part of the snubber circuit connection portion region 202 may be provided in the shifted rectangular region of the arm circuit portion, and the other part may be provided outside the shifted rectangular region of the arm circuit portion.

Likewise, it is not necessary to provide the entire AC terminal connection portion 203 in a rectangular region in which one of the upper arm circuit portion 201U and the lower arm circuit portion 201L is shifted from the other in the x direction or the y direction. At least a part of the AC terminal connection portion 203 may be provided in the shifted rectangular region of the arm circuit portion, and the other part may be provided outside the shifted rectangular region of the arm circuit portion. In short, one side of the AC terminal connection portion 203 may face the upper arm circuit portion 201U and the other side of the AC terminal connection portion 203 may face the lower arm circuit portion 201L in the shifted region of the arm circuit portion.

According to the above embodiment, the following effects are obtained.

(1) The electric circuit device 100 includes the upper arm circuit portion 201U having the semiconductor element 21U (first switching element), the lower arm circuit portion 201L having the semiconductor element 21L (second switching element) and provided apart from the upper arm circuit portion 201U in the first direction, the positive electrode terminal portion 181 electrically connected to the upper arm circuit portion 201U, the negative electrode connection pattern (negative electrode terminal portion) 155 provided with a gap from the upper arm circuit portion 201U in the first direction and electrically connected to the lower arm circuit portion 201 L, the snubber element 30 provided on the region including the gap between the positive electrode terminal portion 181 and the negative electrode terminal portion 155 and connecting the positive electrode terminal portion 181 and the negative electrode terminal portion 155, and the heat dissipation member 140 stacked on the upper arm circuit portion 201U and the lower arm circuit portion 201L through the drain side/source side insulating members 151 and 153 (insulating layers). The upper arm circuit portion 201U and the lower arm circuit portion 201L are provided so as to be shifted in the second direction orthogonal to the direction in which the upper arm circuit portion 201U and the lower arm circuit portion 201L are separated from each other, and at least a part of the snubber circuit connection portion region 202 constituted by the positive electrode terminal portion, the negative electrode terminal portion, and the snubber element 30 is provided in the first region generated by shifting the upper arm circuit portion 201U from the lower arm circuit portion 201L in the second direction. Accordingly, the eddy current generated by the occurrence of inductance when the switching element is turned on and off forms a substantially rectangular loop without distortion. This can reduce the distortion of the inductance loop and improve the inductance reduction effect.

(2) The upper arm circuit portion 201U and the lower arm circuit portion 201L are shifted from each other in the positive direction of the second direction to generate the first region on the end portion side on the positive direction side of the lower arm circuit portion 201L and the second region on the end portion side on the negative direction side of the upper arm circuit portion 201U, and at least a part of the AC terminal connection portion 203 is provided in the second region. Therefore, the closed circuit constituted by the upper arm circuit portion 201U, the lower arm circuit portion 201L, the snubber circuit connection portion region 202, and the AC terminal connection portion 203 forms a substantially rectangular loop with less distortion. This can further improve the inductance reduction effect.

(3) The pair of heat dissipation members 140 are respectively provided above and below the upper arm circuit portion 201U and the lower arm circuit portion 201L so as to sandwich them. As described above, since the heat dissipation members 140 are respectively provided above and below the upper arm circuit portion 201U and the lower arm circuit portion 201L, the heat dissipation effect can be improved as compared with the configuration in which the heat dissipation member 140 is provided on one of the upper and lower arm circuit portions 201U and 201L.

(4) The heat dissipation member 140 extends from above the upper arm circuit portion 201U and above the lower arm circuit portion 201L to above the snubber circuit connection portion region 202. Therefore, the heat generated from the snubber element 30 can be dissipated by the heat dissipation member 140.

In the above embodiment, the switching element is exemplified as a MOSFET. However, for example, a switching element other than the MOSFET such as an insulated gate bipolar transistor (IGBT) can also be used. When an IGBT is used as the switching element, a diode needs to be disposed between the emitter and the collector.

In the above embodiment, the electric circuit device 100 is exemplified as a 2 in 1 module. However, the present invention can be applied to n (n≥2) in 1 modules.

In each of the above embodiments, the upper arm circuit portion 201U and the lower arm circuit portion 201L have been exemplified as shapes having substantially the same lengths in the x direction and the y direction. However, the upper arm circuit portion 201U and the lower arm circuit portion 201L may have different lengths in the x direction or the y direction.

Although various modifications have been described above, the present invention is not limited to these contents. Various embodiments and modifications described above may be combined or appropriately modified, and other aspects conceivable within the scope of the technical idea of the present invention are also included in the scope of the present invention.

### REFERENCE SIGNS LIST

21L semiconductor element (second switching element)
21U semiconductor element (first switching element)
21LD drain terminal (first terminal)
21LN negative electrode terminal portion
21UD drain terminal (first terminal)
21UP positive electrode terminal portion
21LS source terminal (second terminal)
21US source terminal (second terminal)
30 snubber element
100 electric circuit device
115, 116 upper/lower conducting conductor
140 heat dissipation member
151 drain side insulating member (insulating layer)
152L drain side conductor pattern (second conductor pattern)
152U drain side conductor pattern (first conductor pattern)
153 source side insulating member (insulating layer)
154L source side conductor pattern (fourth conductor pattern)
154U source side conductor pattern (third conductor pattern)
155 negative electrode connection pattern (negative electrode terminal portion)
161L heat spreader (second heat spreader)
161U heat spreader (first heat spreader)
162L heat spreader (fourth heat spreader)
162U heat spreader (third heat spreader)
181 positive electrode terminal portion
2011, lower arm circuit portion
201U upper arm circuit portion
202 snubber circuit connection portion region
203 AC terminal connection portion

1. An electric circuit device comprising:
an upper arm circuit portion including a first switching element;
a lower arm circuit portion provided to be separated from the upper arm circuit portion in a first direction and having a second switching element;
a positive electrode terminal portion electrically connected to the upper arm circuit portion;
a negative electrode terminal portion provided with a gap from the upper arm circuit portion in the first direction and electrically connected to the lower arm circuit portion;
a snubber element provided on a region including the gap between the positive electrode terminal portion and the negative electrode terminal portion and connecting the positive electrode terminal portion and the negative electrode terminal portion; and
a heat dissipation member stacked on the upper arm circuit portion and the lower arm circuit portion through an insulating layer,
wherein the upper arm circuit portion and the lower arm circuit portion are provided to be shifted from each other in a second direction orthogonal to the first direction, and
at least a part of a snubber circuit connection portion region constituted by the positive electrode terminal portion, the negative electrode terminal portion, and the snubber element is provided in a first region generated when the upper arm circuit portion and the lower arm circuit portion are shifted in the second direction.

2. The electric circuit device according to claim 1, wherein the upper arm circuit portion and the lower arm circuit portion are shifted from each other in a positive direction of the second direction to generate the first region on the end portion side on the positive direction side of the lower arm circuit portion and the second region on the end portion side on the negative direction side of the upper arm circuit portion, and at least a part of the AC terminal connection portion is provided in the second region.

3. The electric circuit device according to claim 1, wherein a pair of the heat dissipation members are respectively provided above and below the upper arm circuit portion and the lower arm circuit portion so as to sandwich the upper arm circuit portion and the lower arm circuit portion.

4. The electric circuit device according to claim 1, wherein the heat dissipation member extends from above the upper arm circuit portion and above the lower arm circuit portion to above the snubber circuit connection portion region.

5. The electric circuit device according to claim 2, wherein the upper arm circuit portion, the lower arm circuit portion, the snubber circuit connection portion region, and the AC terminal connection portion form a rectangular planar region.

6. The electric circuit device according to claim 1, further comprising:
a first heat spreader joined to a first terminal of the first switching element;
a first conductor pattern joined to the first heat spreader;
a second heat spreader joined to a second terminal of the first switching element;
a second conductor pattern joined to the second heat spreader;
a third heat spreader joined to a first terminal of the second switching element;
a third conductor pattern joined to the third heat spreader;
a fourth heat spreader joined to a second terminal of the second switching element;
a fourth conductor pattern joined to the fourth heat spreader; and
an upper/lower conducting conductor connecting the second conductor pattern and the third conductor pattern.
